(19) United States
(12) Patent Application Publication
(10) Pub. No.: US 2023/0272137 A1
(43) Pub. Date: Aug. 31, 2023

(54) CROSSLINKABLE FLUOROPOLYMER AND COATING FORMED THEREFROM

(71) Applicant: THE CHEMOURS COMPANY FC, LLC, WILMINGTON, DE (US)

(72) Inventor: XUDONG CHEN, HOCKESSIN, DE (US)

(73) Assignee: THE CHEMOURS COMPANY FC, LLC, WILMINGTON, DE (US)

(21) Appl. No.: 18/015,294

(22) PCT Filed: Jul. 9, 2021
(86) PCT No.: PCT/US2021/040985

§ 371 Date: Jan. 9, 2023

Related U.S. Application Data
(60) Provisional application No. 63/050,266, filed on Jul. 10, 2020.

(51) Int. Cl. C08F 214/26; C09D 127/18

(52) U.S. Cl. CPC C08F 214/267; C09D 127/18

(57) ABSTRACT

Provided is a high oil contact angle coating comprising fluoropolymer, compositions and processes for forming the coating, and articles comprising the coating. The fluoropolymer is a crosslinkable tetrapolymer fluoropolymer produced from the copolymerization of monomers tetrafluoroethylene, fluoro(alkyl vinyl ether) or fluoro(alkyl ethylene), alkyl vinyl ether and alkenyl silane. The fluoropolymer coating has high oil contact angle and utility as coating when the fluoropolymer is in the uncrosslinked or crosslinked state.

### CROSS REFERENCE TO RELATED APPLICATIONS

This application claims priority of U.S. Provisional Application No. 63/050,266 filed Jul. 10, 2020, the disclosures of which are incorporated herein by reference in its entirety.

### FIELD OF THE DISCLOSURE

The present disclosure is directed to a high oil contact angle coating comprising fluoropolymer, compositions and processes for forming the coating and articles comprising the coating. The fluoropolymer is a crosslinkable tetrapolymer produced from the copolymerization of tetrafluoroethylene, fluoro(alkyl vinyl ether) or fluoro(alkyl ethylene), alkyl vinyl ether and alkenyl silane.

### BACKGROUND OF DISCLOSURE

Polymers are used in electronic devices to provide structural support and insulation as well as for protecting the device from physical damage and from water. The value of these polymers in these applications is greatly increased if the polymers are crosslinkable, for example photocrosslinkable, allowing for formation of patterns with defined dimensions, so as to provide a three-dimensional framework for the interconnection of multiple electronic components and layers.

As electronic devices and their features become smaller, move to higher frequencies and have lower power consumption, conventional materials used in the manufacture of electronic devices such as polyimides are not able to meet the demands for new materials having desirable properties such as lower dielectric constant, lower loss tangent, lower moisture absorption, adhesion to substrates and higher fluid contact angles. Conventional polymers used in this field have dielectric constants in the range of from 3.0 to 3.3 for example, and unacceptable water absorptivities ranging from 0.8 to 1.7 percent for example.

Water absorption is a significant drawback of conventional polyimides in electronic device applications and can result in the formation of acids which cause corrosion of metals and inorganics in the devices. Such corrosion is undesirable as it can result in device failure through erosion of signal transmission quality and delamination of the passivation layer from the surface coated. Further, water absorption of a passivation layer is undesirable from the point of view of dielectric constant, which is very sensitive to and undesirably raised by increased water content of polymers comprising passivation layers. These deficiencies are especially a concern in newer electronic devices wherein data is transmitted at high frequency. The higher the frequency of operation of the device, the more sensitive it is to performance deterioration from absorbed water.

As electronic devices and device features become smaller, the dielectric constant of insulating materials used between conductors becomes an increasingly significant factor in device performance. As the distance between adjacent conductors become smaller, the resulting capacitance, a function of the dielectric property of the insulating material divided by the distance between conductive paths, increases. The increase in capacitance causes increased capacitive coupling, cross-talk, between adjacent conductors which carry signals across the chip. The increased capacitance further results in increased power consumption for the integrated circuit and an increased resistor-capacitor time constant, the latter resulting in reduced signal propagation speed. The effects of miniaturization cause increased power consumption, limit achievable signal speed, and degrade noise margins used to insure proper integrated circuit device operation. One way to reduce power consumption and cross talk is to decrease the dielectric constant of the insulator, or dielectric, which separates the conductors. The most common semiconductor dielectric is silicon dioxide, which has a dielectric constant (k) of about 3.9. In contrast, air (including partial vacuum) has a dielectric constant of just over 1. Still other insulating materials can provide films having low dielectric constants in the range of approximately 2.0 to 3.0, significantly lower than that of the silicon dioxide films. Therefore, it is well-known that reduced capacitance in the use of certain organic or inorganic insulating materials can result in the alleviation of the aforementioned problems of capacitive coupling and the like.

Many dielectric materials have been proposed for use as dielectric film coatings in semiconductor devices, but most of them are considered to be unsatisfactory in meeting the stringent electrical and physical requirements. The dielectric film-forming materials include inorganic materials which are applied over a patterned wiring layered structure by chemical vapor deposition (CVD) processes. Typical examples of useful inorganic dielectric materials include silicon dioxide, silicon nitride and phosphosilicate glass. The preferred formation of these inorganic dielectrics by CVD processes leaves these inorganic dielectric layers inherently defective because plasma based deposition processes reproduce the uneven and stepped profile structure of the underlying wiring pattern. On the other hand, several organic and organic/inorganic dielectric materials such as polyimide resins, organic spin-on-glass, and other similar dielectric materials have generally been unsatisfactory in one or more of the desired electrical or physical properties of a dielectric coating and/or related materials/coatings. For example, several polyimide resins demonstrate high moisture absorption due to their polarizing chemical structures.

Electrowetting is the phenomenon of contact angle decrease under the influence of an external voltage applied across a solid/liquid interface. Electrowetting has become a widely used tool for manipulating tiny amounts of liquids on surfaces. Electrowetting has shown the potential of microscale fluid motion manipulation by changing the surface tension, which has been widely used in applications such as chemistry, bioengineering, ‘lab-on-a-chip’ devices and sensors, and electronic displays. Electrowetting displays reflect ambient light to provide a paper-like display with competitive advantages such as capable of video playback, low power consumption, sunlight readability, and reading comfort. Coatings of fluoropolymers have found commercial utility in electrowetting applications due to the high contact angles exhibited by liquids such as oils and water on such coatings. The performance of electrowetting displays benefits from fluoropolymer coatings having maximized oil contact angle.

There is a continuing need for improved fluorinated polymeric materials for use as coating layers in electronic devices that have low dielectric constant, low water absorptivity and exhibit improved oil contact angles, while also exhibiting suitable adhesion to substrates. It is additionally beneficial if such fluorinated polymeric materials can be photocrosslinked, for increased coating strength and allowing the coating to be photoimaged to produce fine line structure coatings for electronic components and layers.

### SUMMARY OF THE DISCLOSURE

The present disclosure addresses these needs by providing in one embodiment a photocrosslinkable fluoropolymer consisting essentially of repeat units arising from the monomers: (a) tetrafluoroethylene; (b) fluoro(alkyl vinyl ether) or fluoro(alkyl ethylene) wherein the fluoroalkyl group has 1 to 10 carbon atoms; (c) alkyl vinyl ether wherein the alkyl group is a C1 to C6 straight chain alkyl radical or a C3 to C6 branched chain or cyclic alkyl radical; and (d) ethylenically unsaturated silane of the formula SiR1 R2R3R4, wherein R1 is an ethylenically unsaturated hydrocarbon radical, R2 and R3 are independently selected from substituted or unsubstituted aryl, substituted or unsubstituted aryl substituted hydrocarbon radical, substituted or unsubstituted linear or branched alkoxy radical, substituted or unsubstituted cyclic alkoxy radical, substituted or unsubstituted linear or branched alkyl radical, or substituted or unsubstituted cyclic alkyl radical, and R4 is substituted or unsubstituted linear or branched alkoxy radical, or substituted or unsubstituted cyclic alkoxy radical.

In another embodiment the present disclosure relates to a coating layer comprising a layer of photocrosslinkable coating composition disposed on at least a portion of a substrate, wherein the coating composition comprises the aforementioned photocrosslinkable fluoropolymer wherein: the photocrosslinkable fluoropolymer has a number average molecular weight of from about 10,000 to about 350,000 daltons; the coating composition has an oil contact angle of at least 38 as measured by the Contact Angle Method described herein, and the layer of photocrosslinked coating composition has a thickness of from about 0.5 to about 15 micrometers.

In another embodiment the present disclosure relates to a coating layer comprising a layer of crosslinked coating composition disposed on at least a portion of a substrate, wherein the coating composition comprises: i) the aforementioned crosslinkable fluoropolymer, ii) a photoacid generator; and iii) an optional photosensitizer; wherein: the crosslinkable fluoropolymer has a number average molecular weight of from about 10,000 to about 350,000 daltons, the crosslinked coating composition has an oil contact angle of at least 38 as measured by the Contact Angle Method described herein, and the layer of crosslinked coating composition has a thickness of from about 0.5 to about 15 micrometers, and optionally has photocrosslinked features having a width of about 0.5 micrometers or greater.

In another embodiment the present disclosure relates to a process for forming a photocrosslinked coating, comprising: (1) providing a photocrosslinkable coating composition comprising: i) the aforementioned photocrosslinkable fluoropolymer; ii) a photoacid generator; iii) an optional photosensitizer; and iv) a carrier medium; (2) applying a layer of the photocrosslinkable coating composition onto at least a portion of a substrate; (3) removing at least a portion of the carrier medium; (4) irradiating at least a portion of the layer of the photocrosslinkable coating composition with ultraviolet light; (5) heating the applied layer of photocrosslinkable coating composition; and (6) removing at least a portion of the uncrosslinked photocrosslinkable fluoropolymer resulting in the photocrosslinked coating; wherein the photocrosslinkable fluoropolymer has a number average molecular weight of from about 10,000 to about 350,000 daltons; the photocrosslinked coating composition has an oil contact angle of at least 38 as measured by the Contact Angle Method described herein, and the layer of photocrosslinked coating has a thickness of from about 0.5 to about 15 micrometers and optionally has photocrosslinked features having a width of about 0.5 micrometers or greater.

In another embodiment the present disclosure relates to a composition for forming a photocrosslinked fluoropolymer coating comprising: i) the aforementioned photocrosslinkable fluoropolymer; ii) a photoacid generator; iii) an optional photosensitizer; and iv) a carrier medium.

### BRIEF DESCRIPTION OF THE DRAWINGS

The drawings described herein are for illustration purposes only. The drawings are not necessarily to scale, with emphasis being placed upon illustrating the principles of the following disclosure. The drawings are not intended to limit the scope of the present disclosure in any way.

FIG. 1 shows a photomicrograph (with added measurement bars) of a plan view of a wafer having a patterned coating layer in accordance with one embodiment of the present invention.

### DETAILED DESCRIPTION

The features and advantages of the present disclosure will be more readily understood by those of ordinary skill in the art from reading the following detailed description. It is to be appreciated that certain features of the disclosure, which are, for clarity, described above and below in the context of separate embodiments, may also be provided in combination in a single element. Conversely, various features of the disclosure that are, for brevity, described in the context of a single embodiment, may also be provided separately or in any sub-combination. In addition, references to the singular may also include the plural (for example, “a” and “an” may refer to one or more) unless the context specifically states otherwise.

The use of numerical values in the various ranges specified in this application, unless expressly indicated otherwise, are stated as approximations as though the minimum and maximum values within the stated ranges were both proceeded by the word “about”. In this manner, slight variations above and below the stated ranges can be used to achieve substantially the same results as values within the ranges. Also, the disclosure of these ranges is intended as a continuous range including each and every value between the minimum and maximum values.

As used herein:

The term “photocrosslinked” means a crosslinked fluoropolymer wherein the crosslinks within the polymer network are formed as a result of the action of light. For example, compositions comprising the crosslinkable fluoropolymer also containing one or more of a photoacid generator and an optional photosensitizer have utility for photocrosslinking. Irradiating the composition with light of the appropriate wavelength generates acid functional molecules that react with the silane groups on the crosslinkable fluoropolymer resulting in the crosslinking of the crosslinkable fluoropolymer.

The phrases “crosslinkable fluoropolymer” and “photocrosslinkable fluoropolymer” mean an uncrosslinked crosslinkable fluoropolymer that is capable of being crosslinked, for example, by treatment with acid, thermally, or when irradiated with the appropriate wavelength of light in the presence of one or more of a photoacid generator and, optionally, a photosensitizer.

The phrase “photocrosslinked features” refers to the size of the structures that can be produced according to the process of the present disclosure. The photocrosslinked features are defined by the width of the feature formed and by the thickness of the layer of the photocrosslinked coating composition. For example, the disclosed process can form 4 micrometer lines in a coating that is 2 micrometers thick. It should be noted that the photocrosslinked feature refers to the void that is formed when the uncrosslinked fluoropolymer is removed. For example, where a series of lines are formed, the photocrosslinked feature refers to the width of the void produced when the uncrosslinked fluoropolymer material is removed forming the void. The photocrosslinked features can be formed by irradiating a portion of a layer of the coating composition, heating the applied layer of coating composition, then removing the uncrosslinked portions of the coating composition, for example, by dissolving and carrying away uncrosslinked portions in a solvent.

The phrase “passivation layer” means a layer that provides the underlying substrate to which it is attached protection from environmental damage. For example, damage from water, oxidation and chemical degradation. The passivation layer has both barrier properties and forms a dielectric layer on the substrate that can be used to separate two conductor layers or two semiconductor layers or a conductive layer from a semiconductor layer. The passivation layer can also be used as a bank layer in a light emitting diode structure that separates the various wells of light emitting diode material from contacting one another.

The phrase “unreactive solvent” means one or more solvents for the crosslinkable fluoropolymer or for the coating composition comprising the crosslinkable fluoropolymer wherein the unreactive solvent does not become a part of the final crosslinked polymer network as a result of the crosslinking with the crosslinkable fluoropolymer.

In on composition wherein the coating composition comprises crosslinkable fluoropolymer either in the non-crosslinked or crosslinked state. In one embodiment the coating layer is a passivation layer. The coating layer can be used as a barrier layer and/or an insulating layer in a thin film transistor, organic field effect transistor, semiconductor, semiconductor oxide field effect transistor, integrated circuit, light emitting diode (LED), bank layers for LEDs, including organic LEDs, display device, flexible circuit, solder mask, photovoltaic device, printed circuit board, an interlayer dielectric, optical waveguide, a micro electromechanical system (MEMS), a layer of an electronic display device or a layer of a microfluidic device or chip. In the embodiment where the crosslinkable fluoropolymer is crosslinked after forming a coating layer, the coating layer can form a layer that is in the form of a patterned surface for electrowetting applications. Such crosslinked coating compositions can provide very small photocrosslinked features and provides low dielectric constant, low water absorptivity, high oil contact angle and good adhesion to electronic device substrates.

The present disclosure includes a crosslinkable fluoropolymer consisting essentially of repeat units arising from the monomers: (a) tetrafluoroethylene; (b) fluoro(alkyl vinyl ether) or fluoro(alkyl ethylene) as described subsequently herein; (c) alkyl vinyl ether as described subsequently herein; and (d) ethylenically unsaturated silane as described subsequently herein.

The crosslinkable fluoropolymer consists essentially of 40 to 59 mole percent repeat units arising from tetrafluoroethylene and fluoro(alkyl vinyl ether) or fluoro(alkyl ethylene), based on the total amount of repeat units in the fluoropolymer, and in some embodiments 42 to 58 mole percent of such repeat units, and in some embodiments 45 to 55 mole percent of such repeat units.

The crosslinkable fluoropolymer consists essentially of 40 to 59 mole percent repeat units arising from alkyl vinyl ether, based on the total amount of repeat units in the fluoropolymer, and in some embodiments 42 to 58 mole percent of such repeat units, and in some embodiments 45 to 55 mole percent of such repeat units.

The crosslinkable fluoropolymer consists essentially of 0.2 to 10 mole percent repeat units arising from ethylenically unsaturated silane, based on the total amount of repeat units in the fluoropolymer, and in some embodiments 1.2 to 8 mole percent of such repeat units, and in some embodiments 1.4 to 7 mole percent of such repeat units.

In some embodiments, the crosslinkable fluoropolymer consists of the aforementioned amounts of tetrafluoroethylene, fluoro(alkyl vinyl ether) or fluoro(alkyl ethylene), alkyl vinyl ether, and alkenyl silane.

The relative mole ratio of repeat units arising from tetrafluoroethylene to fluoro(alkyl vinyl ether) or fluoro(alkyl ethylene) in the present crosslinkable fluoropolymer ranges from 10:1 to 1:10, in another embodiment from 10:1 to 1:9, in another embodiment from 10:1 to 1:8, in another embodiment from 10:1 to 1:7, in another embodiment from 10:1 to 1:6, in another embodiment from 10:1 to 1:5, in another embodiment from 10:1 to 1:4, in another embodiment from 10:1 to 1:3, in another embodiment from 10:1 to 1:2, in another embodiment from 10:1 to 1:1, in another embodiment from 5:1 to 1:1, in another embodiment from 5:1 to 1.5:1, in another embodiment from 3:1 to 1.5:1; in another embodiment from 1:1.5 to 1.5:1, in another embodiment from 1:1.4 to 1.4:1, in another embodiment from 1:1.3 to 1.3:1, in another embodiment from 1:1.2 to 1.2:1, and in another embodiment about 1:1.

The present crosslinkable fluoropolymer contains repeat units arising from the monomer (b) fluoro(alkyl vinyl ether) or fluoro(alkyl ethylene). The term “or” as used here is inclusive, meaning that the present crosslinkable fluoropolymer can contain repeat units arising from fluoro(alkyl vinyl ether), or fluoro(alkyl ethylene), or a combination of fluoro(alkyl vinyl ether) and fluoro(alkyl ethylene). In one embodiment, fluoro(alkyl vinyl ether) and fluoro(alkyl ethylene) can be represented by the general formula:

CXY═CZ—Oa-RF

wherein:
a is either 0 (fluoro(alkyl ethylene) embodiment) or 1 (fluoro(alkyl vinyl ether) embodiment),
X, Y and Z are independently selected from H and F, preferably all are F (trifluorovinyl), and
RF is a saturated fluoroalkyl radical having in one embodiment from 1 to 40 carbon atoms, in another embodiment from 1 to 10 carbon atoms, and in a preferred embodiment from 1 to 3 carbon atoms. In a preferred embodiment RF is perfluorinated. RF can be linear, branched or cyclic. In an optional embodiment RF is substituted with ether oxygen. In one embodiment the oxygen containing fluoroalkyl radical is characterized by having a saturated chain structure in which oxygen atoms in the backbone are separated by saturated fluorocarbon repeating groups having from 1 to 3 carbon atoms, preferably perfluorocarbon groups, examples of which include —CF₂O—, —CF₂CF₂O—, —CF₂CF₂CF₂O—, and —CF(CF₃)CF₂O—, that can occur alone or together. In one embodiment, X, Y and Z are H, a is 0, and the RF radical includes a —CH₂—O—CH₂— moiety attached to the ethylene group of the fluoro(alkyl ethylene). For example, fluoro(alkyl ethylene)s being represented by the formula CH₂═CH—CH₂—O—CH₂—RF.

Example fluoro(alkyl vinyl ether)s include: perfluoro(methyl vinyl ether), perfluoro(ethyl vinyl ether), perfluoro(propyl vinyl ether), perfluoro(n-butyl vinyl ether), CF₃(CF₂)₇OCF═CF₂, CF₂═CFOCF(CF₃)CF₂OCF₂CF₂CF₃, CF₃OCF₂OCF₂OCF₂CF₂OCF═CF₂, C₃F₇OCF(CF₃)CF₂OCF═CF₂, CF₃CF₂CF₂O(CF(CF₃)CF₂O)ₙCF═CF₂ wherein n is an integer, preferably from 3-7. Example fluoro(alkyl ethylene)s include: CF₃(CF₂)ₙCF═CF₂ wherein n is 0 or an integer, preferably from 1 to 10, and CF₃(CF₂)ₙCH═CH₂ wherein n is 0 or an integer, preferably from 1 to 10. Example fluoro(alkyl ethylenes)s containing allylic groups include CF₃CF₂CF₂O(CF(CF₃)CF₂O)ₙCF(CF₃)CH₂OCH₂CH═CH₂, wherein n is an integer, preferably from 10 to 12, or alternately where n is an integer from 20-24, and (CF₃CF(CF₃)O(CF₂O)ₙCF(CF₃)CH₂OCH₂CH═CH₂, wherein n is an integer, preferably from 1 to 5.

The present crosslinkable fluoropolymer contains repeat units arising from the monomer (c) alkyl vinyl ether. Alkyl vinyl ethers as used herein are those wherein the alkyl group is a C1 to C6 straight chain saturated hydrocarbon radical or a C3 to C6 branched chain or cyclic saturated hydrocarbon radical. Example alkyl vinyl ethers include methyl vinyl ether, ethyl vinyl ether, n-propyl vinyl ether, isopropyl vinyl ether, n-butyl vinyl ether, sec-butyl vinyl ether, t-butyl vinyl ether, n-pentyl vinyl ether, isoamyl vinyl ether, hexyl vinyl ether, and cyclohexyl vinyl ether. In some embodiments, the alkyl vinyl ether consists of or consists essentially of methyl vinyl ether, ethyl vinyl ether, n-propyl vinyl ether, isopropyl vinyl ether or a combination thereof.

The present crosslinkable fluoropolymer contains repeat units arising from the monomer (d) ethylenically unsaturated silane. In one embodiment, the ethylenically unsaturated silane is of the formula SiR1 R2R3R4, wherein R1 is an ethylenically unsaturated hydrocarbon radical, R2 and R3 are independently selected from substituted or unsubstituted aryl, substituted or unsubstituted aryl substituted hydrocarbon radical, substituted or unsubstituted linear or branched alkoxy radical, substituted or unsubstituted cyclic alkoxy radical, substituted or unsubstituted linear or branched alkyl radical, or substituted or unsubstituted cyclic alkyl radical, and R4 is substituted or unsubstituted linear or branched alkoxy radical, or substituted or unsubstituted cyclic alkoxy radical.

In a preferred embodiment the ethylenically unsaturated silane is of the formula SiR1 R2R3R4, wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical, or substituted or unsubstituted cyclic C5-C6 alkoxy radical.

In one embodiment the ethylenically unsaturated silane R1 ethylenically unsaturated hydrocarbon radical is an unsaturated hydrocarbon radical capable of productively copolymerizing into the crosslinkable fluoropolymer backbone together with the other required monomers: tetrafluoroethylene, fluoro(alkyl vinyl ether) or fluoro(alkyl ethylene) and alkyl vinyl ether. In some embodiments the ethylenically unsaturated hydrocarbon radicals are those having from 2 to 5 carbon atoms. In some embodiments the ethylenically unsaturated hydrocarbon radical is ethenyl (vinyl), 2-propenyl (allyl), 1-propenyl, 2-butenyl, 1,3-butadienyl, 2-pentenyl, and the like. In a preferred embodiment the ethylenically unsaturated hydrocarbon radical is ethenyl.

In one embodiment the ethylenically unsaturated silane R2 radical is aryl, aryl substituted hydrocarbon radical, branched C3-C6 alkoxy radical or substituted or unsubstituted cyclic C5-C6 alkoxy radical. The R2 radical was chosen by the present inventor to be a relatively sterically bulky substituent bonded to the silicon atom of the silane. This was discovered by the present inventor to allow for productive copolymerization and incorporation of the alkenyl silane through the ethylenically unsaturated hydrocarbon radical into the crosslinkable fluoropolymer backbone chain, and also result in the fluoropolymer having phase stable shelf-life, for example, such that it remains dissolved in organic solvent and does not undesirably form gel at ambient temperatures and without special precautions for at least 3 months (e.g, does not form gel through hydrolysis of the silane alkoxy radicals, followed by silicon-oxygen crosslinking (e.g., —Si—O—Si—)). In one embodiment R2 is aryl, for example phenyl, naphthyl or the like. In another embodiment R2 is an aryl substituted hydrocarbon radical, for example benzyl, —CH2CH2C6H5, or the like. In another embodiment R2 is a branched C3-C6 alkoxy radical. In another embodiment R2 is a substituted or unsubstituted cyclic C5-C6 alkoxy radicals. Example R2 radicals include isopropoxy (—OCH(CH₃)CH₃, 2-propoxy), isobutoxy (1 methylpropoxy, —OCH(CH₃)CH₂CH₃), secbutoxy (2-methylpropoxy, —OCH₂CH(CH₃)CH₃)), tertbutoxy (2-methyl-2-propoxy, —OC(CH₃)₃)), and the like. In a preferred embodiment R2 is isopropoxy.

In one embodiment the ethylenically unsaturated silane R3 and R4 radicals are independently selected from linear or branched C1-C6 alkoxy radicals, or substituted or unsubstituted cyclic C5-C6 alkoxy radicals. In one embodiment, R3 and R4 are identical.

In one embodiment the ethylenically unsaturated silane is a trialkoxy silane in which the R2, R3, and R4 radicals are identical.

Example ethylenically unsaturated silanes include: vinyltriisopropoxysilane, allyltriisopropoxysilane, butenyltriisopropoxysilane, and vinylphenyldimethoxysilane. In a preferred embodiment, the ethylenically unsaturated silane is vinyltriisopropoxysilane. In some embodiments, the ethylenically unsaturated silane consists of, or consists essentially of vinyltriisopropoxysilane. Such ethylenically unsaturated silanes are commercially available, for example from Gelest Inc., Morrisville, Pa., USA.

In accordance with some embodiments, the crosslinkable fluoropolymer has a weight average molecular weight of from 10,000 to 350,000 daltons. In accordance with other embodiments, the crosslinkable fluoropolymer has a weight average molecular weight of from 100,000 to 350,000 daltons. In other embodiments, crosslinkable fluoropolymer weight average molecular weight can be in a range comprising a minimum weight average molecular weight to a maximum weight average molecular weight wherein the minimum is 10,000, or 20,000, or 30,000, or 40,000, or 50,000, or 60,000, or 70,000, or 80,000, or 90,000, or 100,000, or 110,000, or 120,000, or 125,000, or 130,000, or 140,000, or 150,000, or 160,000 or 170,000 and the maximum is 350,000, or 340,000, or 330,000, or 320,000, or 310,000 or 300,000 daltons. In one embodiment the crosslinkable fluoropolymer has a weight average molecular weight of 200,000 daltons.

The present crosslinkable fluoropolymers can be produced according to known methods. In some embodiments, the monomers can be polymerized without the use of a solvent, and in other embodiments the monomers can be polymerized in a solvent, which may or may not be a solvent for the crosslinkable fluoropolymer. In other embodiments, the crosslinkable fluoropolymer can be produced by the emulsion polymerization of the monomers. To produce the desired crosslinkable fluoropolymer, the monomers, at least one free radical initiator and, optionally, an acid acceptor can be charged to an autoclave and heated to a temperature of from 25° C. to 200° C. for 10 minutes to 24 hours at a pressure of from atmospheric pressure to as high as 1,500 atmospheres. The resulting product can then be removed from the autoclave, filtered, rinsed and dried to give the crosslinkable fluoropolymer.

Suitable free radical initiators used in the polymerization methods to manufacture the crosslinkable fluoropolymer can be any of the known azo and/or peroxide type initiators. For example, di(4-t-butylcyclohexyl)dicarbonate, di-t-butyl peroxide, acetyl peroxide, lauroyl peroxide, benzoyl peroxide, 2,2-azodiisobutyronitrile, 2,2-azobis(2,4-dimethyl-4-methoxyvaleronitrile), dimethyl-2,2-azobis(isobutyrate) or a combination thereof can be used. The amount of free radical initiators that can be used range of from 0.05 to 4 percent by weight, based on the total amount of the monomers in the monomer mixture. In other embodiments, the amount of free radical initiators used is from 0.1 to 3.5 percent by weight, and, in still further embodiments, is from 0.2 percent by weight to 3.25 percent by weight. All percentages by weight are based on the total amount of the monomers in the monomer mixture.

An acid acceptor can also be used in the polymerization methods to form the crosslinkable fluoropolymer. The acid acceptor can be a metal carbonate or metal oxide, for example, sodium carbonate, calcium carbonate, potassium carbonate, magnesium carbonate, barium oxide, calcium oxide, magnesium oxide or a combination thereof. The acid acceptor can be present from 0 to 5 percent by weight. In other embodiments, the acid acceptor can be present from 0.1 percent by weight to 4 percent by weight, and, in still further embodiments, can be present from 0.2 percent by weight to 3 percent by weight. All percentages by weight are based on the total amount of the monomers in the monomer mixture. The acid acceptor is present in order to neutralize acids, such as hydrogen fluoride that may be present in the fluorinated monomers or may be generated during the course of the polymerization.

In one embodiment the present disclosure relates to a coating composition for forming a crosslinkable fluoropolymer coating comprising i) the present crosslinkable fluoropolymer and ii) a carrier medium. In another embodiment the present disclosure relates to a coating composition for forming a photocrosslinked fluoropolymer coating comprising i) the present crosslinkable fluoropolymer, ii) a photoacid generator, iii) an optional photosensitizer; and iv) a carrier medium. The coating composition can also optionally comprise v) an additive. The coating composition enables the manufacture of a continuous coating of the crosslinkable fluoropolymer on a substrate. Optionally, subsequent to formation of the continuous coating, the crosslinkable fluoropolymer can be crosslinked. The coating composition can be prepared by simply mixing the components together at room temperature in the desired proportions. The major components of the coating composition are the crosslinkable fluoropolymer and the carrier medium. Generally, the coating composition comprises from 5 to 35 weight percent of crosslinkable fluoropolymer and from 65 to 95 weight percent of carrier medium. Above 35 weight percent crosslinkable fluoropolymer the viscosity of the coating composition becomes difficult to coat at room temperature. Below 5 weight percent of crosslinkable fluoropolymer the thickness of the films generated (in a one coat coating process) become too thin for utility as coating layer. In some embodiments the coating composition comprises from 10 to 30 weight percent of crosslinkable fluoropolymer and from 70 to 90 weight percent of carrier medium. In the embodiment where the crosslinkable fluoropolymer is to be photocrosslinked, the present coating composition will further comprise photoacid generator. Suitable ii) photoacid generators are known in the art and can include, for example, (p-isopropylphenyl)(p-methylphenyl)iodonium tetrakis(pentafluorophenyl)-borate, IRGACURE® GSID-26-1 which is a salt of tris[4-(4-acetylphenyl)sulfanylphenyl] sulfonium and tris(trifluoromethanesulfonyl)methide and is available from BASF, Florham Park, N.J., bis(1,1-dimethylethylphenyl)iodonium salt with tris[(trifluoromethane)sulfonyl]methane also available from BASF, bis(4-decylphenyl)iodonium hexafluoroantimonate oxirane, mono[(C12-C14-alkoxy)methyl] derivatives, available from Momentive as UV9387C, 4,4′,4″-tris(t-butylphenyl)sulfonium triflate, 4,4′-di-t-butylphenyl iodonium triflate, diphenyliodonium tetrakis(pentafluorophenyl)sulfonium borate, triarylsulfonium-tetrakis(pentafluorophenyl) borate, triphenylsulfonium tetrakis(pentafluorophenyl) sulfonium borate, 4,4′-di-t-butylphenyl iodonium tetrakis(pentafluorophenyl) borate, tris(t-butylphenyl) sulfonium tetrakis(pentafluorophenyl) borate, 4-methylphenyl-4-(1-methylethyl)phenyl iodonium tetrakis(pentafluorophenyl) borate or a combination thereof. IRGACURE® GSID-26-1 photoacid generator is especially useful as it does not require the separate addition of a photosensitizer. The photoacid generator can be present in the coating composition in an amount from 0.01 to 5 percent by weight, based on the total amount of the coating composition minus carrier medium. In other embodiments, the photo acid generator can be present from 0.1 to 2 percent by weight, and, in still further embodiments, can be present in an amount from 0.3 to 1.0 percent by weight, based on the total amount of the coating composition minus carrier medium.

In the embodiment where the crosslinkable fluoropolymer is to be photocrosslinked, the coating composition for forming the present photocrosslinked fluoropolymer coating can also optionally comprise a iii) photosensitizer. Suitable photosensitizers can include, for example, chrysenes, benzopyrenes, fluoranthrenes, pyrenes, anthracenes, phenanthrenes, xanthones, indanthrenes, thioxanthen-9-ones or a combination thereof. In some embodiments, the photosensitizer can be 2-isopropyl-9H-thioxanthen-9-one, 4-isopropyl-9H-thioxanthen-9-one, 1-chloro-4-propoxythioxanthone, 2-isopropylthioxanthone, phenothiazine or a combination thereof. The optional photosensitizer can be used in an amount from 0 to 5 percent by weight, the percentage by weight based on the total amount of the coating composition minus carrier medium. In other embodiments, the photosensitizer can be present in the coating composition in an amount from 0.05 to 2 percent by weight, and, in still further embodiments, from 0.1 to 1 percent by weight. All percentages by weight reported for photoacid generator and photosensitizer in the present coating compositions are based on the total weight of solid components in the coating composition.

The coating composition for forming the crosslinkable fluoropolymer coating is typically applied to at least a portion of a substrate as a solution or dispersion of the coating composition in iv) a carrier medium (solvent). This allows a layer of the coating composition to be applied and results in a smooth defect-free layer of coating composition on the substrate. Suitable carrier medium can include, for example, ketones, ethers, ether esters and halocarbons. In some embodiments, for example, the carrier medium can be a ketone, for example, acetone, acetylacetone, methyl ethyl ketone, methyl isobutyl ketone, methyl amyl ketone, 2-pentanone, 3-pentanone, 2-heptanone, 3-heptanone, cyclopentanone, cyclohexanone; ester, for example, ethyl acetate, propyl acetate, butyl acetate, isobutyl acetate, pentyl acetate, cyclohexyl acetate, heptyl acetate, ethyl propionate, propyl propionate, butyl propionate, isobutyl propionate, propylene glycol monomethyl ether acetate, propylene glycol monoethyl ether acetate, methyl lactate, ethyl lactate, gamma-butyrolactone; ether, for example, diisopropyl ether, dibutyl ether, ethyl propyl ether, anisole; or halocarbon, for example, dichloromethane, chloroform, tetrachloroethylene; or a combination thereof of the named carrier medium. In some embodiments, the carrier medium is methyl isobutyl ketone, 2-heptanone, propylene glycol methyl ether acetate or a combination thereof. In some embodiments, the solvent is an unreactive solvent, meaning that the carrier medium does not become a part of the photocrosslinked coating after the curing step.

The coating composition can also comprise v) one or more optional additives. Suitable additives can include, for example, viscosity modulators, fillers, dispersants, binding agents, surfactants, antifoaming agents, wetting agents, pH modifiers, biocides, bacteriostats or a combination thereof. Such additives are well known in the art. Typically, the additives comprise less than 10 percent by weight of the coating composition.

The present disclosure also relates in one embodiment to a thermal process for forming a crosslinked coating comprising (1) providing a photocrosslinkable coating composition comprising: i) a crosslinkable fluoropolymer as defined earlier herein; and ii) a carrier medium; (2) applying a layer of the crosslinkable coating composition onto at least a portion of a substrate; (3) removing at least a portion of the carrier medium; and (4) heating the applied layer of photocrosslinkable coating composition to thermally crosslink the crosslinkable fluoropolymer. The (4) heating step can be carried out at ambient temperature through temperatures up to 250° C. under air or inert atmosphere for a period of time that can be easily determined by the average practitioner, typically from minutes at higher temperatures to up to days under ambient conditions. In other embodiments, the heating can be done at a temperature of from 60 to 150° C., and in still further embodiments, at a temperature of from 80° C. to 130° C. The coating composition can be exposed to the elevated temperature for 15 seconds to 10 minutes. In other embodiments, the time can be from 30 seconds to 5 minutes, and in still further embodiments, from 1 to 3 minutes.

The present disclosure also relates in one embodiment to an acid catalyzed process for forming a crosslinked coating comprising (1) providing a photocrosslinkable coating composition comprising: i) a crosslinkable fluoropolymer as defined earlier herein; ii) a carrier medium; and iii) an acid catalyst; (2) applying a layer of the crosslinkable coating composition onto at least a portion of a substrate; (3) removing at least a portion of the carrier medium; and optionally (4) heating the applied layer of photocrosslinkable coating composition to crosslink the crosslinkable fluoropolymer. The (4) heating step can be carried out at ambient temperature through temperatures up to 250° C. under air or inert atmosphere for a period of time that can be easily determined by the average practitioner to suitably crosslink the crosslinkable fluoropolymer, typically from minutes at higher temperatures to up to days under ambient conditions. The acid catalyst can be any acid that productively catalyzes crosslinking of the present crosslinkable fluoropolymer without negatively effecting desirable properties of the crosslinked coating. Example acid catalysts include sulfuric acid and trifluoracetic acid. In one embodiment, the acid catalyst can comprise a Lewis acid, such as titanium (IV) Lewis acids, such as titanium (IV) acetate.

The present disclosure also relates in one embodiment to a process for forming a photocrosslinked coating comprising: (1) providing a photocrosslinkable coating composition comprising: i) a crosslinkable fluoropolymer as defined earlier herein; ii) a photoacid generator; iii) an optional photosensitizer; and iv) a carrier medium; (2) applying a layer of the photocrosslinkable coating composition onto at least a portion of a substrate; (3) removing at least a portion of the carrier medium; (4) irradiating at least a portion of the layer of the photocrosslinkable coating composition with ultraviolet light; (5) heating the applied layer of photocrosslinkable coating composition; and (6) removing at least a portion of the uncrosslinked crosslinkable fluoropolymer.

The thickness of the applied layer of coating composition is from 0.5 to 15 micrometers. In some embodiments, the thickness of the applied layer of coating composition is from 1 to 15 micrometers. In some embodiments, the thickness of the applied layer of coating composition is from 4 to 10 micrometers.

The layer of the present coating composition can be applied to a variety of substrates, including electrically conductive materials, semiconductive materials and/or nonconductive materials. For example, the substrate can be glass, polymeric, inorganic semiconductor, organic semiconductor, tin oxide, zinc oxide, titanium dioxide, silicon dioxide, indium oxide, indium zinc oxide, zinc tin oxide, indium gallium oxide, gallium nitride, gallium arsenide, indium gallium zinc oxide, indium tin zinc oxide, cadmium sulfide, cadmium selenide, silicon nitride, copper, aluminum, gold, titanium or a combination thereof. The layer of the present coating composition can be applied by spin coating, spray coating, flow coating, curtain coating, roller coating, brushing, inkjet printing, screen printing, offset printing, gravure printing, flexographic printing, lithographic printing, dip coating, blade coating or drop coating methods. Spin coating involves applying an excess amount of the present coating composition to the substrate, then rotating the substrate at high speeds to spread the composition by centrifugal force. The thickness of the resultant film can be dependent on the spin coating rate, the concentration of the crosslinkable fluoropolymer in the present coating composition, as well as the carrier medium used. Ambient conditions such as temperature, pressure, and humidity can also affect the thickness of the applied layer of coating composition.

After application to the substrate, and prior to the heating step in the embodiment where the coating composition is thermally crosslinking, and prior to irradiation (photocrosslinking) in the embodiment where the coating composition is photocrosslinked, at least a portion of the carrier medium can be removed by exposing the applied layer of coating composition to elevated temperatures, exposure to less than atmospheric pressure, by directly or indirectly blowing gas onto the applied layer, or by using a combination of these methods. For example, the applied layer of coating composition may be heated in air or in a vacuum oven optionally with a small purge of nitrogen gas. In other embodiments, the applied layer of coating composition can be heated to a temperature of from 60 to 110° C. for a brief period of time, generally minutes, in order to remove the carrier medium.

In the embodiment where the coating composition is to be photocrosslinked, at least a portion of the applied layer of crosslinkable coating composition can be irradiated (i.e., photocrosslinked) by exposure to light. The light is typically ultraviolet (UV) light at a wavelength of 150 to 500 nanometers (nm). In some embodiments, the ultraviolet light can be at a wavelength of from 200 to 450 nanometers, and, in other embodiments, from 325 to 425 nm. In still further embodiments, the exposure can be carried out by exposure to multiple wavelengths, or by irradiation at selected wavelengths, for example, 404.7 nanometers, 435.8 nanometers or 365.4 nanometers. Many suitable UV lamps are known in the industry and can be used.

The crosslinkable coating composition can be photocrosslinked using UV-A light. Crosslinking can be achieved when the total exposure to the light source is from 10 millijoules/centimeter² (millijoules/cm²) to 10,000 millijoules/cm². In other embodiments, the ultraviolet light exposure can be from 50 to 600 millijoules/cm². Exposure can be carried out in air or a nitrogen atmosphere.

Optionally, in order to form crosslinked features, at least a portion of the applied layer of crosslinkable coating composition can be irradiated to begin the crosslinking process only to those portions that were irradiated. The applied layer of crosslinkable coating composition can be masked or the step of irradiation can be performed using a focused light source so that the light contacts only those portions that are to be crosslinked. These techniques are well-known in the art. For example, a mask can be applied directly to the applied layer of crosslinkable coating composition. This method is known as contact printing. In another embodiment, called proximity printing, the mask is held slightly above the applied layer of crosslinkable coating composition without actually contacting the layer. In a third embodiment, an optical exposure device that precisely projects and focuses the light so that an actual physical mask is not needed. In some embodiments, the mask can be a chrome or other metal mask.

After exposure to UV light, the layer of coating composition can be heated. The heating step can be done at a temperature of from 60 to 150° C. In other embodiments, the heating can be done at a temperature of from 60 to 130° C., and in still further embodiments, at a temperature of from 80° C. to 110° C. The coating composition can be exposed to the elevated temperature for 15 seconds to 10 minutes. In other embodiments, the time can be from 30 seconds to 5 minutes, and in still further embodiments, from 1 to 3 minutes.

Once the coating composition has been heated, uncrosslinked crosslinkable coating composition can be removed by dissolving in a carrier medium that dissolves the uncrosslinked crosslinkable fluoropolymer. Occasionally, a small amount of uncrosslinked crosslinkable coating composition can remain after the removal step. Remaining such fluoropolymer can be removed, if necessary, using plasma or a second wash step. The carrier medium can be a mixture of a solvent and a nonsolvent for the crosslinkable fluoropolymer. In some embodiments, the ratio of solvent to nonsolvent can be from 1:0 to 3:1. In other embodiments, the ratio of solvent to nonsolvent can be from 1:0.1 to 3:1. The solvents can be any of those that are listed as carrier medium that have the ability to solvate the (uncrosslinked) crosslinkable fluoropolymer. In some embodiments, the solvent can be methyl isobutyl ketone, 2-heptanone, propylene glycol monomethyl ether acetate or a combination thereof. In other embodiments, the nonsolvent can be hexane and/or isopropanol. In some embodiments, the application of the solvents to remove uncrosslinked photocrosslinkable coating composition can be carried out in a step-wise fashion. In one embodiment, a two-step process can be used, wherein the first step involves treatment with solvent or mixture of a solvent and a nonsolvent, and the second step involves treatment with nonsolvent or a mixture of a solvent and a nonsolvent. In another embodiment, a multi-step process can be used, for example a three-step process, wherein the first step involves treatment with solvent, the second step involves treatment with a mixture of a solvent and a nonsolvent, and the third step involves treatment with nonsolvent.

In some embodiments, after removal of uncrosslinked crosslinkable coating composition using solvent, the substrate containing the applied layer of crosslinked coating composition can be final thermally cured, sometimes referred to in this field as “hard baking”. This heating step can be carried out on the present crosslinked coating composition at a temperature of from 170° C. to 210° C., preferably 190° C., for a time period of from 0.5 to 3 hours. In other embodiments, this heating step can be carried out at even higher temperatures, and for relatively shorter periods of time, provided that these higher temperatures do not negatively affect the coated substrate. The final hard baking step provides a final crosslinked coating composition on the substrate, and the resultant electronic device can then be further processed as necessary.

The coating layer of the present disclosure can also be used as a bank layer in a light emitting diode. In this particular application, the coating layer can be used to separate one diode from another, for example, in the production of a display device using organic light emitting diodes, the bank layer can act as a barrier layer separating the red, blue and green light emitting diodes. It can be especially useful as a bank layer for organic light emitting diodes.

In one embodiment the present disclosure relates to a coating layer comprising a layer of crosslinked coating composition disposed on at least a portion of a substrate.

The present coating compositions have dielectric constants of from about 2.0 to about 3.0 when measured at 1 MHz. Dielectric constant values closer to 2.0 are obtainable by maximizing the fluorine content of the fluoropolymer used to form the coating. In one embodiment, this can be accomplished by maximizing within the ranges disclosed earlier herein, the amounts of repeating units in the crosslinkable fluoropolymer arising from fluorinated monomer (i.e., tetrafluoroethylene, fluoro(alkyl vinyl ether), fluoro(alkyl ethylene)) relative to the amounts of repeating units arising from the other monomers (i.e., alkyl vinyl ether and ethylenically unsaturated silane).

The present coating composition, whether crosslinked or not, surprisingly has an oil contact angle of at least 38, preferably at least 40, and more preferably at least 50. The present coating composition, whether crosslinked or not, has a water contact angle of at least 99, preferably at least 100, and more preferably at least 110. Contact angles of the present coatings are measured by the methods described in the present Examples. Contact angles are desirably maximized for coating applications such as microfluidic devices (biosensors) and electrowetting based electronic displays. Higher contact angles are obtainable by maximizing the fluorine content of the fluoropolymer used to form the coating.

The present coating, whether crosslinked or not, in one embodiment can have a thickness of from 0.5 to 15 micrometers. In some embodiments, the thickness of the applied layer of coating composition is from 1 to 15 micrometers. In some embodiments, the thickness of the applied layer of coating composition is from 4 to 10 micrometers. In one embodiment, the photocrosslinked coating optionally has photocrosslinked features (vias) having a width of about 0.5 micrometers or greater.

The present coatings in one embodiment have water absorption values ranging from about 0.01 to about 0.8 percent by weight as measured by dynamic vapor sorption at standard temperature from 90% to 10% relative humidity.

### EXAMPLES

### Source of Chemicals

a) PGMEA (1-Methoxy-2-propyl acetate, Lithography Grade, from JT Baker, JTB-6343-05, Center Valley, Pa.)
b) Vinyl triisopropoxysilane (Gelest Chemicals, SIV9210, Morrisville, Pa.)
c) Solkane 365mfc (Solvay)
d) Ethyl vinyl ether (Alfa Aesar, A15691-0F, Ward Hill, Mass.)
e) Potassium carbonate, anhydrous (EMD, PX1390-1, Philadelphia, Pa.)
f) V-601 initiator, dimethyl 2,2′-azobisisobutyrate (Wako Chemicals, Richmond, Va.)
   Other monomers (manufactured by Chemours by literature methods): PPVE (perfluoro(propyl vinyl ether)), PMVE (perfluoro(methyl vinyl ether)), C₃F₇OCF(CF₃)CF₂OCF═CF₂, CF₃(CF₂)₇OCF═CF₂, CF₃(CF₂)₄CF═CF₂, 2VE (CF₃OCF₂OCF₂OCF₂CF₂OCF═CF₂), AE2 (CF₃CF₂CF₂O(CF(CF₃)CF₂O)ₙCF(CF₃)CH₂OCH₂CH═CH₂), mixture of compounds having n=10-12), AE4 (CF₃CF₂CF₂O(CF(CF₃)CF₂O)ₙCF(CF₃)CH₂OCH₂CH═CH₂), mixture of compounds n=22-24), KVE (CF₃CF₂CF₂O(CF(CF₃)CF₂O)ₙCF═CF₂), n=5.

### Comparative Synthesis Example 1 (CE1): Preparation of Poly (TFE/Ethyl Vinyl Ether/Vinyl Triisopropoxysilane)

A 400 mL autoclave is chilled to −20 C then loaded with 0.5 g K₂CO₃, 0.24 g V601, 3.2 g vinyl triisopropoxysilane, 36 g ethyl vinyl ether, and 250 g Solkane 365mfc. The autoclave is evacuated and further loaded with 50 g TFE. The reaction mixture is shaken and heated to 66 C. The pressure in the autoclave peaks at 173 PSIg, dropping to 34 PSIg 8 hours later. Upon cooling, a viscous liquid (298 g) is obtained and is transferred to a 300 mL jar. To the polymer solution is added 100 g acetone and then the mixture is rolled on a roll mill until it becomes a uniform solution. The polymer solution is then transferred to a Nordson filter cartridge and passed through a 0.2-0.45 um micropore filter (Whatman Polycap HD 2610T) under 30 PSI air pressure. The polymer solution after filtration was collected in a pan lined with PFTE film and dried in a vacuum oven for 3 days. Obtained was 61.0 g dry polymer. Nuclear magnetic resonance spectroscopy (19F and 1H NMR) shows the composition of polymer to be: 50.7 mol % TFE, 47.5 mol % ethyl vinyl ether, 1.8 mol % vinyl triisopropoxysilane. Size exclusion chromatography (SEC) in hexafluoroisopropanol shows: Mn=1.22×10⁵, Mw=1.71×10⁵.

### Synthesis Example 1 (SE1): Preparation of Poly (TFE/Ethyl Vinyl Ether/PPVE/Vinyl Triisopropoxysilane)

A 400 mL autoclave is chilled to below −20° C. and loaded with 0.5 g K₂CO₃, 0.24 g V601, 3.2 g vinyl triisopropoxysilane, 36 g ethyl vinyl ether, and 250 g Solkane 365mfc. The autoclave was evacuated and further loaded with 50 g TFE, and 5 g perfluoro(propyl vinyl ether) (PPVE). The reaction mixture is shaken and heated to 66 C. The pressure in the autoclave peaks at 200 PSIg, dropping to 76 PSIg 8 hours later. Upon cooling, a viscous liquid (305 g) is obtained and is transferred to a 300 mL jar, and to which 100 g acetone is added. The solution is rolled on a roll mill until it becomes uniform. The solution is transferred to a Nordson filter cartridge and passed through a 0.2-0.45 um micropore filter (Whatman Polycap HD 2610T) under 30 PSI air pressure. The polymer solution after filtration is collected in a pan lined with PFTE film and then dried in a vacuum oven for 3 days. Obtained is 62.0 g dry polymer. Nuclear magnetic resonance spectroscopy (19F and 1H NMR) shows the composition of polymer to be: 48.6 mol % TFE, 48.1 mol % ethyl vinyl ether, 1.6 mol % vinyl triisopropoxysilane, and 1.7 mol % PPVE. SEC in hexafluoroisopropanol shows: MN=119,540, Mw=179,700.

### Synthesis Example 2 (SE2): Preparation of Poly (TFE/Ethyl Vinyl Ether/PPVE/Vinyl Triisopropoxysilane)

The procedure of Synthesis Example 1 (SE1) is duplicated except for the following changes: 20 g perfluoro(propyl vinyl ether) (PPVE) is loaded to the autoclave together with the TFE; the pressure in the autoclave peaks at 190 PSIg, dropping to 32 PSIg 8 hours later; upon cooling, a viscous liquid (327 g) is obtained; after vacuum drying, obtained is 82.0 g dry polymer. Nuclear magnetic resonance spectroscopy (19F and 1H NMR) shows the composition of polymer to be: 43.1 mol % TFE, 48.3 mol % ethyl vinyl ether, 1.8 mol % vinyl triisopropoxysilane, and 6.7 mol % PPVE.

### Synthesis Example 3 (SE3): Preparation of Poly (TFE/Ethyl Vinyl Ether/PPVE/Vinyl Triisopropoxysilane) (30 g PPVE)

The procedure of Synthesis Example 1 (SE1) is duplicated except for the following changes: 30 g perfluoro(propyl vinyl ether) (PPVE) is loaded to the autoclave together with the TFE; the pressure in the autoclave peaks at 200 PSIg, dropping to 76 PSIg 8 hours later; upon cooling, a viscous liquid (340 g) is obtained; after vacuum drying, obtained is 78.8 g dry polymer. Nuclear magnetic resonance spectroscopy (19F and 1H NMR) shows the composition of polymer to be: 40.1 mol % TFE, 47.8 mol % EVE, 1.8 mol % vinyl triisopropoxysilane, 9.8 mol % PPVE. SEC in hexafluoroisopropanol shows: Mn=87,630, Mw=141,530.

### Synthesis Example 4 (SE4): Preparation of Poly (TFE/Ethyl Vinyl Ether/PPVE/Vinyl Triisopropoxysilane) (53.2 g PPVE)

The procedure of Synthesis Example 1 (SE1) is duplicated except for the following changes: 53.2 g perfluoro(propyl vinyl ether) (PPVE) is loaded to the autoclave together with the TFE; the pressure in the autoclave peaks at 176 PSIg, dropping to 36 PSIg 8 hours later; upon cooling, a viscous liquid (366 g) is obtained; after vacuum drying, obtained is 93.2 g dry polymer. Nuclear magnetic resonance spectroscopy (19F and 1H NMR) shows the composition of polymer to be: 28.9 mol % TFE, 48.9 mol % ethyl vinyl ether, 1.3 mol % vinyl triisopropoxysilane, and 20.5 mol % PPVE. SEC in hexafluoroisopropanol shows: MN=7.42×10⁴, Mw=1.08×10⁵.

### Synthesis Example 5 (SE5): Preparation of Poly (TFE/Ethyl Vinyl Ether/PMVE/Vinyl Triisopropoxysilane)

The procedure of Synthesis Example 1 (SE1) is duplicated except for the following changes: 40 g perfluoro(methyl vinyl ether) (PMVE) is loaded to the autoclave together with the TFE; the pressure in the autoclave peaks at 189 PSIg, dropping to 42 PSIg 8 hours later; upon cooling, a viscous liquid (305 g) is obtained; after vacuum drying, obtained is 65.1 g dry polymer. Nuclear magnetic resonance spectroscopy (19F and 1H NMR) shows the composition of polymer to be: 32.0 mol % TFE, 47.4 mol % EVE, 1.7 mol % vinyl triisopropoxysilane, 18.8 mol % PMVE. SEC in hexafluoroisopropanol shows: Mn=118,000, Mw=172,000.

### Synthesis Example 6 (SE6): Preparation of Poly (TFE/Ethyl Vinyl Ether/2VE/Vinyl Triisopropoxysilane)

The procedure of Synthesis Example 1 (SE1) is duplicated except for the following changes: 5 g CF₃OCF₂OCF₂OCF₂CF₂OCF═CF₂ (2VE) is loaded to the autoclave together with the K2CO3, vinyl triisopropoxysilane, ethyl vinyl ether and Solkane 365mfc; the pressure in the autoclave peaks at 196 PSIg, dropping to 45 PSIg 8 hours later; upon cooling, a viscous liquid (300 g) is obtained; after vacuum drying, obtained is 42.1 g dry polymer. Nuclear magnetic resonance spectroscopy (19F and 1H NMR) shows the composition of polymer to be: 49.1 mol % TFE, 47.5 mol % EVE, 1.6 mol % vinyl triisopropoxysilane, 0.8 mol % 2VE. SEC in hexafluoroisopropanol shows: Mn=98,330, Mw=140,870.

### Synthesis Example 7 (SE7): Preparation of Poly (TFE/Ethyl Vinyl Ether/CF₃(CF₂)₇OCF═CF₂/Vinyl Triisopropoxysilane)

The procedure of Synthesis Example 1 (SE1) is duplicated except for the following changes: 5 g CF₃(CF₂)₇OCF═CF₂ is loaded to the autoclave together with the K2CO3, vinyl triisopropoxysilane, ethyl vinyl ether and Solkane 365mfc; the pressure in the autoclave peaks at 188 PSIg, dropping to 140 PSIg 8 hours later; upon cooling, a viscous liquid (298 g) is obtained; after vacuum drying, obtained is 59.5 g dry polymer. Nuclear magnetic resonance spectroscopy (19F and 1H NMR) shows the composition of polymer to be: 48.7 mol % TFE, 48.5 mol % ethyl vinyl ether, 1.7 mol % vinyl triisopropoxysilane, and 0.8 mol % CF₃(CF₂)₇OCF═CF₂.

### Synthesis Example 8 (SE8): Preparation of Poly (TFE/Ethyl Vinyl Ether/CF₃(CF₂)₄CF═CF₂/Vinyl Triisopropoxysilane)

The procedure of Synthesis Example 1 (SE1) is duplicated except for the following changes: 5 g CF₃(CF₂)₄CF═CF₂ is loaded to the autoclave together with the K2CO3, vinyl triisopropoxysilane, ethyl vinyl ether and Solkane 365mfc; the pressure in the autoclave peaks at 198 PSIg, dropping to 70 PSIg 8 hours later; upon cooling, a viscous liquid (298 g) is obtained; after vacuum drying, obtained is 56.5 g dry polymer. Nuclear magnetic resonance spectroscopy (19F and 1H NMR) shows the composition of polymer to be: 50.0 mol % TFE, 47.3 mol % ethyl vinyl ether, 1.4 mol % vinyl triisopropoxysilane, and 1.1 mol % CF₃(CF₂)₄CF═CF₂.

### Synthesis Example 9 (SE9): Preparation of Poly (TFE/Ethyl Vinyl Ether/AE2/Vinyl Triisopropoxysilane)

The procedure of Synthesis Example 1 (SE1) is duplicated except for the following changes: 5 g CF₃CF₂CF₂O(CF(CF₃)CF₂O)ₙCF(CF₃)CH₂OCH₂CH═CH₂, n=10, (AE2) is loaded to the autoclave together with the K2CO3, vinyl triisopropoxysilane, ethyl vinyl ether and Solkane 365mfc; the pressure in the autoclave peaks at 185 PSIg, dropping to 28 PSIg 8 hours later; upon cooling, a viscous liquid (305 g) is obtained; after vacuum drying, obtained is 64.6 g dry polymer. Nuclear magnetic resonance spectroscopy (19F and 1H NMR) shows the composition of polymer to be: 50.1 mol % TFE, 48.1 mol % EVE, 1.4 mol % vinyl triisopropoxysilane, 0.2 mol % AE2. SEC in hexafluoroisopropanol shows: Mn=114,450, Mw=171,580.

### Synthesis Example 10 (SE10): Preparation of Poly (TFE/Ethyl Vinyl Ether/AE4/Vinyl Triisopropoxysilane)

The procedure of Synthesis Example 1 (SE1) is duplicated except for the following changes: 10 g CF(CF₃)(CF₂O)ₙCF(CF₃)CH₂OCH₂CH═CH₂, n=2 (AE4) is loaded to the autoclave together with the K2CO3, vinyl triisopropoxysilane, ethyl vinyl ether and Solkane 365mfc; the pressure in the autoclave peaks at 193 PSIg, dropping to 25 PSIg 8 hours later; upon cooling, a viscous liquid (315 g) is obtained; after vacuum drying, obtained is 51.8 g dry polymer. Nuclear magnetic resonance spectroscopy (19F and 1H NMR) shows the composition of polymer to be: 50.5 mol % TFE, 47.7 mol % EVE, 1.5 mol % vinyl triisopropoxysilane, 0.3 mol % AE4. SEC in hexafluoroisopropanol shows: Mn=114,450, Mw=171,580.

### Synthesis Example 11 (SE11): Preparation of Poly (TFE/Ethyl Vinyl Ether/KVE/Vinyl Triisopropoxysilane)

The procedure of Synthesis Example 1 (SE1) is duplicated except for the following changes: 5 g CF₃CF₂CF₂O(CF(CF₃)CF₂O)ₙCF═CF₂, n=5 (KVE) is loaded to the autoclave together with the K2CO3, vinyl triisopropoxysilane, ethyl vinyl ether and Solkane 365mfc; the pressure in the autoclave peaks at 187 PSIg, dropping to 20 PSIg 8 hours later; upon cooling, a viscous liquid (309 g) is obtained; after vacuum drying, obtained is 67.0 g dry polymer. Nuclear magnetic resonance spectroscopy (19F and 1H NMR) shows the composition of polymer to be: 50.8 mol % TFE, 47.5 mol % EVE, 1.5 mol % vinyl triisopropoxysilane, 0.2 mole % KVE. SEC in hexafluoroisopropanol shows: Mn=128,000, Mw=256,000.

Spin Coating of Glass Slides with 10% Polymer in PGMEA Solution

10% polymer solution in PGMEA is made by shaking the mixture on a Burrell Wrist-Action shaker for 4 h. 3×1 inch glass slide is placed on a spin coater vacuum chuck, and 1.25 mL solution is added to the slide surface. The slide is spun at 1000 RPM for 30 seconds. The slide is then dried on a 70 C hotplate for 3 minutes. The thickness of the coating is measured to be about 1 um.

### Method for Measuring Water and Oil Contact Angle

A Ramé Hart goniometer is used to record the water contact angle of the coated surface. A single 10 μL drop of deionized water is used. The contact angle is recorded. The measurement is performed a total of three times per slide at different locations on the slide.

A VCA optima goniometer is used to record the oil contact angle of the coated surface. A single 10 μL drop of hexadecane is used. The contact angle is recorded. The measurement is performed a total of three times per slide at different locations on the slide.

Contact Angle Measurements

| | Oil Contact Angle (up to | Water Contact Angle (up to |
|---|---|---|
| | two measurements per | two measurements per slide, |
| | slide, from different | from different locations on |
| Examples | locations on slide) | slide) |
| CE1 | 28.1, 27.8 | 98.8, 98.0 |
| SE1 | 39.2, 39.4 | 99.6, 101.8 |
| SE2 | 52.5, 51.3 | 103.1, 106.3 |
| SE3 | 54.9, 55.1 | 105.2, 105.8 |
| SE4 | 57.9, 28.3 | — |
| SE5 | 56.9, 58.1 | 112.8, 112.8 |
| SE7 | 43.5 | 91.5 |
| SE8 | 48.0 | 105.9 |
| SE9 | 49.3 | 105.1 |

Passivation Formulation from Polymer SE7

Fluoropolymer SE7 (6.00 g) is dissolved in 25 g PGMEA (0.97 g/mL) in a clean amber bottle by shaking overnight in a wrist shaker. To this solution, 2-isopropylthioxathone (0.030 g) and p-isopropylphenyl)(p-methylphenyl) iononium tetrakis(pentafluorophenyl) borate (0.030 g) is added and is mixed by rolling on roller mill for about 30 min.

Patterned Wafer Using Passivation Formulation from Polymer SE7

A 3-inch silicon wafer is cleaned with pressurized water followed by acetone, and then isopropanol (IPA) and dried completely using pressurized N₂. The wafer is put on a spin coater and visually centered. Approximately 1.2 mL of the SE7 Passivation Formulation described above is poured onto the wafer and spread at 500 rpm for 7 sec. The wafer is then spun for 30 sec at 2,500 rpm. The wafer is then spun for 7 sec at 1,000 rpm. Once the spinning is stopped, the coated wafer is removed from the spin coater and it is baked for 150 sec at 77° C. on a precision hot plate. The baked wafer is exposed to ˜350 mJ/cm² UV light on NXQ8000 mask aligner with a custom designed mask. After the exposure, post-exposure baking of the wafer is carried out at 75° C. for 120 seconds. Two solvent baths containing PGMEA and IPA are used for the developing step. The wafer is put into the PGMEA bath first, and the whole bath is gently shaken in circular motion for 4 min. Then the wafer is transferred to the IPA bath, and the whole bath is gently shaken in circular motion for 1 min. After these steps, the wafer is brought out of the IPA bath and dried using pressurized N₂ gun. The coated wafer is cured at 75° C. for 2 min on a precision hot plate. It is cooled to room temperature and images of the patterns are obtained via an optical microscope (Zeiss Axio). Thickness of the coating is ˜5 um measured using spectroscopic ellipsometer with 5-spot measurement method.

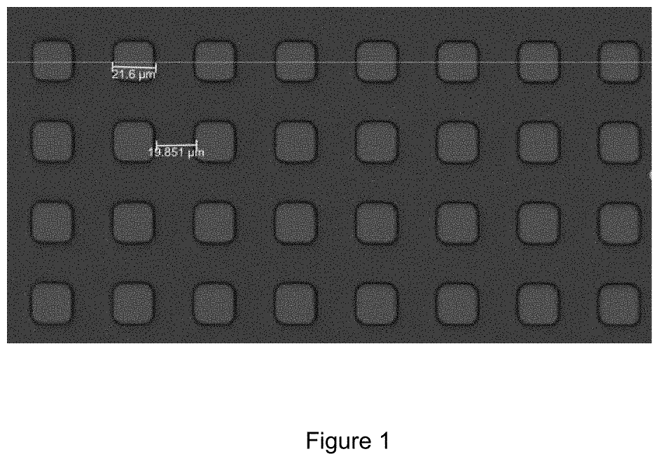

FIG. 1 is an expanded plan view photomicrograph with added measurement bars of features (etched vias) of FIG. 1. FIG. 1 shows 32 of the approximately 20 micrometer square vias separated by approximately 20 micrometer regions of photocrosslinked fluoropolymer SE7.

1. A crosslinkable fluoropolymer consisting essentially of repeat units arising from the monomers:
(a) tetrafluoroethylene;
(b) fluoro(alkyl vinyl ether) or fluoro(alkyl ethylene) wherein the fluoroalkyl group has 1 to 40 carbon atoms;
(c) alkyl vinyl ether wherein the alkyl group is a C1 to C6 straight chain alkyl radical or a C3 to C6 branched chain or cyclic alkyl radical;
(d) ethylenically unsaturated silane of the formula SiR1 R2R3R4, wherein R1 is an ethylenically unsaturated hydrocarbon radical, R2 and R3 are independently selected from substituted or unsubstituted aryl, substituted or unsubstituted aryl substituted hydrocarbon radical, substituted or unsubstituted linear or branched alkoxy radical, substituted or unsubstituted cyclic alkoxy radical, substituted or unsubstituted linear or branched alkyl radical, or substituted or unsubstituted cyclic alkyl radical, and R4 is substituted or unsubstituted linear or branched alkoxy radical, or substituted or unsubstituted cyclic alkoxy radical.

2. The crosslinkable fluoropolymer of claim 1, wherein said fluoro(alkyl vinyl ether) is a perfluoro(alkyl vinyl ether).

3. The crosslinkable fluoropolymer of claim 1, wherein said fluoro(alkyl ethylene) is a perfluoro(alkyl ethylene).

4. The crosslinkable fluoropolymer of claim 1, wherein said fluoro(alkyl vinyl ether) or fluoro(alkyl ethylene) are represented by the general formula: CXY═CZ—Oa-RF, wherein: a is either 0 or 1; X, Y and Z are independently selected from H and F; and RF is a saturated fluoroalkyl radical having from 1 to 40 carbon atoms.

5. The crosslinkable fluoropolymer of claim 4, wherein RF contains ether oxygen.

6. The crosslinkable fluoropolymer of claim 5, wherein said RF is characterized by having a saturated chain structure in which oxygen atoms in the backbone are separated by saturated fluorocarbon repeating groups having from 1 to 3 carbon atoms.

7. The crosslinkable fluoropolymer of claim 6, wherein said saturated fluorocarbon repeating groups are selected from the group consisting of: —CF₂O—, —CF₂CF₂O—, —CF₂CF₂CF₂O—, and —CF(CF₃)CF₂O—.

8. The crosslinkable fluoropolymer of claim 2, wherein said perfluoro(alkyl vinyl ether) is selected from the group consisting of perfluoro(methyl vinyl ether), perfluoro(ethyl vinyl ether) and perfluoro(propyl vinyl ether), perfluoro(n-butyl vinyl ether), CF₃(CF₂)₇OCF═CF₂, CF₂═CFOCF(CF₃)CF₂OCF₂CF₂CF₃, CF₃OCF₂OCF₂OCF₂CF₂OCF═CF₂, C₃F₇OCF(CF₃)CF₂OCF═CF₂, and CF₃CF₂CF₂O(CF(CF₃)CF₂O)ₙCF═CF₂ wherein n is an integer from 3-7.

9. The crosslinkable fluoropolymer of claim 1, wherein said fluoro(alkyl ethylene) is selected from the group consisting of CF₃(CF₂)₄CF═CF₂, CF₃CF₂CF₂O(CF(CF₃)CF₂O)ₙCF(CF₃)CH₂OCH₂CH═CH₂, wherein n is an integer from 10 to 24, and CF₃CF(CF₃)O(CF₂O)ₙCF(CF₃)CH₂OCH₂CH═CH₂, wherein n is an integer from 1 to 5.

10. The crosslinkable fluoropolymer of claim 1, wherein said alkyl vinyl ether is selected from the group consisting of methyl vinyl ether, ethyl vinyl ether and propyl vinyl ether.

11. The crosslinkable fluoropolymer of claim 1, wherein said ethylenically unsaturated silane is of the formula SiR1 R2R3R4, and wherein R1 is an ethylenically unsaturated hydrocarbon radical, R2 is aryl, aryl substituted hydrocarbon radical, branched C3-C6 alkoxy radical, or substituted or unsubstituted cyclic C5-C6 alkoxy radical, and R3 and R4 are independently selected from linear or branched C1-C6 alkoxy radical, or substituted or unsubstituted cyclic C5-C6 alkoxy radical.

12. A coating layer comprising a layer of coating composition disposed on at least a portion of a substrate, wherein said coating composition comprises:
i) said crosslinkable fluoropolymer of claim 1, wherein:
said crosslinkable fluoropolymer has a number average molecular weight of from about 10,000 to about 350,000 daltons,
said coating composition has an oil contact angle of at least 38 as measured by the Contact Angle Method described herein, and
said layer of coating composition has a thickness of from about 0.5 to about 15 micrometers.

13. A coating layer comprising a layer of crosslinked coating composition disposed on at least a portion of a substrate, wherein said coating composition comprises:
i) said crosslinkable fluoropolymer of claim 1;
ii) a photoacid generator; and
iii) an optional photosensitizer; wherein:
said crosslinkable fluoropolymer has a number average molecular weight of from about 10,000 to about 350,000 daltons,
said crosslinked coating composition has an oil contact angle of at least 38 as measured by the Contact Angle Method described herein, and
said layer of crosslinked coating composition has a thickness of from about 0.5 to about 15 micrometers, and optionally has photocrosslinked features having a width of about 0.5 micrometers or greater.

14. The coating layer of claim 13, wherein said coating composition has water absorption values ranging from about 0.01 to about 0.8 percent by weight as measured by dynamic vapor sorption at standard temperature from 90% to 10% relative humidity.

15. The coating layer of claim 13, wherein said layer of the coating has a thickness of about 4 micrometers to about 10 micrometers.

16. A process for forming a crosslinked coating, comprising:
(1) providing a crosslinkable coating composition comprising:
i) said crosslinkable fluoropolymer of claim 1;
ii) a photoacid generator;
iii) an optional photosensitizer; and
iv) a carrier medium;
(2) applying a layer of the crosslinkable coating composition onto at least a portion of a substrate;
(3) removing at least a portion of the carrier medium;
(4) irradiating at least a portion of the layer of the crosslinkable coating composition with ultraviolet light;
(5) heating the applied layer of crosslinkable coating composition; and
(6) removing at least a portion of the uncrosslinked crosslinkable fluoropolymer resulting in said crosslinked coating;
wherein the crosslinkable fluoropolymer has a number average molecular weight of from about 10,000 to about 350,000 daltons,
said crosslinked coating composition has an oil contact angle of at least 38 as measured by the Contact Angle Method described herein, and
said layer of crosslinked coating has a thickness of from about 0.5 to about 15 micrometers and optionally has photocrosslinked features having a width of about 0.5 micrometers or greater.

17. The process of claim 16, wherein the crosslinkable coating composition comprises about 5 to about 35 percent by weight of the crosslinkable fluoropolymer; from about 65 to about 95 weight percent of carrier medium based on the total weight of all components in the coating composition, and from 0 to about 5 percent by weight of the photosensitizer and from about 0.01 to about 5 percent by weight of the photoacid generator, wherein the percentages by weight of photosensitizer and photoacid generator are based on the total weight of all components in the coating composition minus the carrier medium.

18. The process of claim 16, wherein at least a portion of the carrier medium is removed by exposing the applied layer of crosslinkable coating composition to elevated temperatures, exposure to less than atmospheric pressure, by directly or indirectly blowing gas onto the substrate, or a combination thereof.

19. The process of claim 16 wherein the step (4) of irradiating is performed in air or a nitrogen atmosphere.

20. The process of claim 16, wherein the wavelength of ultraviolet light is from about 325 to about 425 nm.

21. The process of claim 16, wherein the ultraviolet light exposure is from about 10 to about 10,000 millijoules/cm2.

22. The process of claim 16, wherein the heating step (5) occurs at a temperature of from about 60° C. to about 150° C. for about 15 seconds to about 10 minutes.

23. The process of claim 16, wherein the removing step (6) occurs by dissolving the photocrosslinkable fluoropolymer using a carrier medium that dissolves the photocrosslinkable fluoropolymer.

24. An article comprising the coating layer of claim 13.

25. A composition for forming a crosslinked fluoropolymer coating comprising:
i) said crosslinkable fluoropolymer of claim 1;
ii) a photoacid generator;
iii) an optional photosensitizer; and
iv) a carrier medium.

26. The composition of claim 25, wherein the carrier medium is methyl isobutyl ketone, 2-heptanone, propylene glycol methyl ether acetate or a combination thereof.

27. The composition of claim 25, wherein the composition comprises from about 5 to about 35 percent by weight of the crosslinkable fluoropolymer; from about 65 to about 95 weight percent of carrier medium based on the total weight of all components in the coating composition, and from 0 to about 5 percent by weight of the photosensitizer and from about 0.01 to about 5 percent by weight of the photoacid generator, wherein the percentages by weight of photosensitizer and photoacid generator are based on the total weight of all components in the coating composition minus the carrier medium.
